(19) United States
(12) Patent Application Publication
(10) Pub. No.: US 2011/0108974 A1
(43) Pub. Date: May 12, 2011

(54) POWER AND SIGNAL DISTRIBUTION OF INTEGRATED CIRCUITS

(75) Inventors: Yin-Chao Huang, Taipei Hsien (TW); Shi-Bai Chen, Taichung City (TW)

(73) Assignee: MEDIATEK INC., Hsin-Chu (TW)

(21) Appl. No.: 12/613,744

(22) Filed: Nov. 6, 2009

(51) Int. Cl. H01L 23/49

(52) U.S. Cl. 257/690; 257/782; 257/E23.024

(57) ABSTRACT

A packaged integrated circuit is provided comprising a first semiconductor die, a second semiconductor die, and a bonding wire. The first semiconductor die has a first internal bonding pad electrically connected to the package. The second semiconductor die has a second internal bonding pad located in an internal portion of the second semiconductor die. The second internal bonding pad is electrically connected to the first internal bonding pad through the first bonding wire.

### BACKGROUND OF THE INVENTION

1. Field of the Invention

The invention relates to power and signal distribution of an integrated circuit, and more particularly to a power and signal distribution of a multi-chip-module (MCM) integrated circuit.

2. Description of the Related Art

For semiconductor packaging techniques for a multi-chip-module (MCM) integrated circuit, at least two semiconductor dies are mounted in the same package. In one semiconductor die, the portion close to or in the center of the semiconductor die may have long wires to lead fingers of the packages. The long wires generally have relatively large resistance which causes undesired IR voltage drops. Thus, the long wires may result in decreased power and/or signals from the lead fingers.

Thus, it is desired to provide power and signal distribution of an MCM integrated circuit, in which the portions close to or in the center of the semiconductor dies can receive power and/or signals with sufficient intensity from package lead fingers.

### BRIEF SUMMARY OF THE INVENTION

An exemplary embodiment of a packaged integrated circuit comprises a first semiconductor die, a second semiconductor die, and a bonding wire. The first semiconductor die has a first internal bonding pad electrically connected to the package. The second semiconductor die has a second internal bonding pad located in an internal portion of the second semiconductor die. The second internal bonding pad is electrically connected to the first internal bonding pad through the first bonding wire.

Another exemplary embodiment of a packaged integrated circuit comprises a first semiconductor die, a second semiconductor die, a third semiconductor, a first bonding wire, and a second bonding wire. The first semiconductor die has a first internal bonding pad electrically connected to the package. The second semiconductor die has a second internal bonding pad. The third semiconductor die has a third internal bonding pad. At least one of the second internal bonding pad and the third internal bonding pad is located in an internal portion of the corresponding semiconductor die. The second internal bonding pad is electrically connected to the first internal bonding pad through the first bonding wire. The third internal bonding pad is electrically connected to the second internal bonding pad through the second bonding wire.

Another exemplary embodiment of a packaged integrated circuit comprises a first semiconductor die, a plurality of second semiconductor dies, and a plurality of bonding wires. The first semiconductor die has a first internal bonding pad electrically connected to the package. Each second semiconductor die has a second internal bonding pad. The second internal bonding pad of at least one of the second semiconductor dies is located in an internal portion of the corresponding semiconductor die. The first internal bonding pad and the second internal bonding pads are electrically connected in series through the bonding wires, sequentially.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 shows an exemplary embodiment of an integrated circuit with side-by-side semiconductor dies;

FIG. 2 shows another exemplary embodiment of an integrated circuit with side-by-side semiconductor dies;

FIG. 3 shows another exemplary embodiment of an integrated circuit with side-by-side semiconductor dies;

FIG. 4 shows an exemplary embodiment of an integrated circuit with overlapped semiconductor dies; and

FIG. 5 shows another exemplary embodiment of an integrated circuit with overlapped semiconductor dies.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

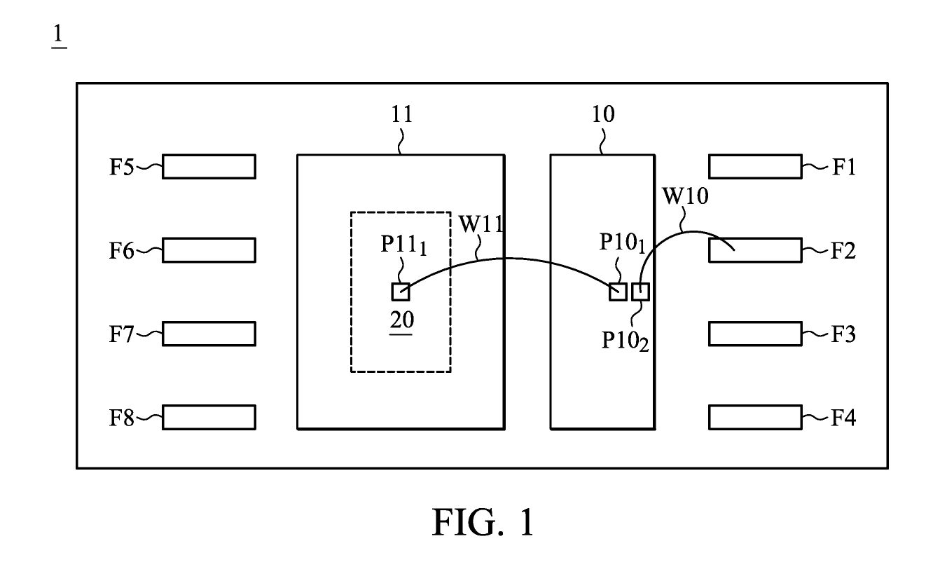

In an exemplary embodiment of a packaged integrated circuit in FIG. 1, an integrated circuit 1 is mounted in a package and comprises at least two semiconductor dies. In the embodiment of FIG. 1, two semiconductor dies 10 and 11 disposed side-by-side are given as an example. The package comprises a plurality of lead fingers, and in FIG. 1, eight lead fingers F1-F8 are given as an example. Referring to FIG. 1, the semiconductor die 10 has an internal bonding pad P10₁ and an input/output (I/O) bonding pad P10₂, which are electrically connected to one lead finger of the package, for example the lead finger F2. The I/O bonding pad P10₂ is electrically connected to the internal bonding pad P10₁ through a trace in the semiconductor die 10 (not shown in FIG. 1). The semiconductor die 11 has an internal bonding pad P11₁ which is located in an internal portion 20 of the semiconductor die 11. The integrated circuit 1 further comprises an I/O bonding wire W10 and a bonding wire W11. The I/O bonding pad P10₂ is electrically connected to the lead finger F2 through the I/O bonding wire W10. Thus, the internal bonding pad P10₁ is electrically connected to the lead finger F2 through the I/O bonding pad P10₂. The internal bonding pad P11₁ is electrically connected to the internal bonding pad P10₁ through the bonding wire W11.

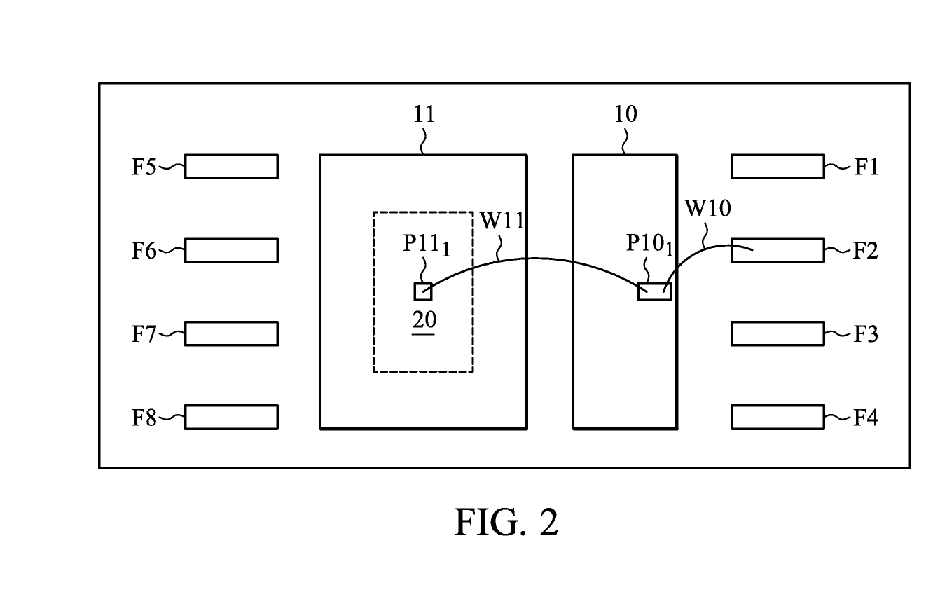

In some embodiments, as shown in to FIG. 2, the I/O bonding pad P10₂ of the semiconductor die 10 is omitted, and the internal bonding pad P10₁ of the semiconductor die 10 is divided into a first portion and a second portion. The first portion of the internal bonding pad P10₁ is electrically connected to the lead finger F2 of the package through the I/O bonding wire W10, and the second portion thereof is electrically connected to the internal bonding pad P11₁ through the bonding wire W11.

According to the embodiments in FIGS. 1 and 2, since the internal bonding pad P11₁ located in the internal portion 20 of the semiconductor die 11 is directly electrically connected to the lead finger F2 through the bonding wire W11 and I/O bonding wire W10, power or signals from the lead finger F2 is not decreased.

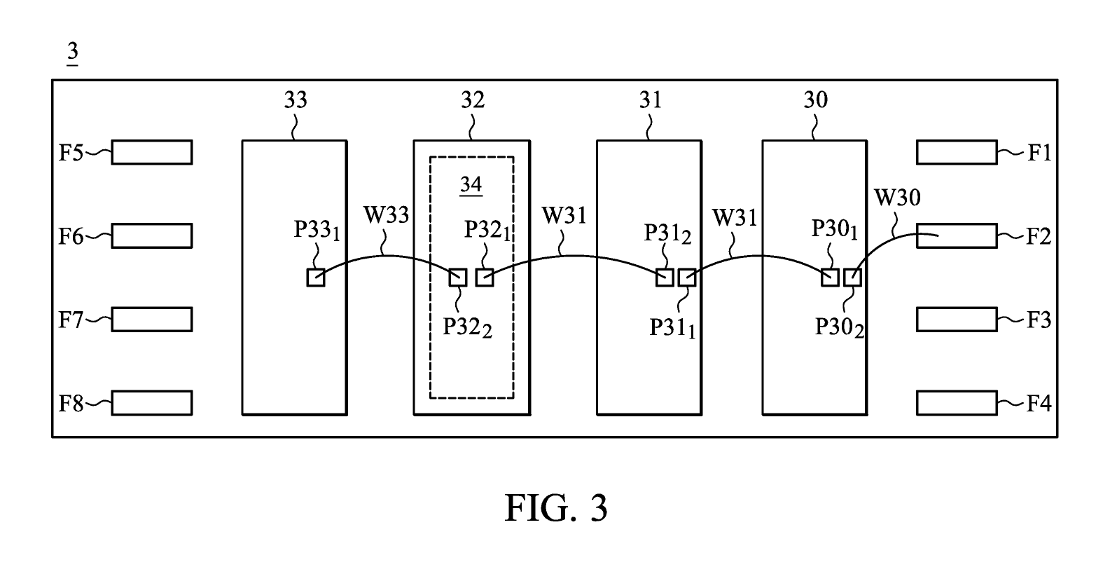

In some embodiments, an integrated circuit may comprise more than two semiconductor dies. As shown in FIG. 3, an integrated circuit 3 further comprises four semiconductor dies 30, 31, 32 and 33 disposed side-by-sides. The integrated circuit 3 is mounted in a package. The package comprises a plurality of lead fingers, and in FIG. 3, eight lead fingers F1-F8 are given as an example. Referring to FIG. 3, the semiconductor die 30 has an internal bonding pad P30₁ and an I/O bonding wire pad P30₂ which are electrically connected to one lead finger of the package, for example the lead finger F2. The I/O bonding pad P30₂ is electrically connected to the internal bonding pad P30₁ through a trace in the semiconductor die 30 (not shown in FIG. 3). The semiconductor die 31 has internal bonding pads P31₁ and P31₂, and the internal bonding pad P31₂ is electrically connected to the internal bonding pad P31₁ through a trace in the semiconductor die 31 (not shown in FIG. 3). The semiconductor die 32 has internal bonding pads P32₁ and P32₂, and the internal bonding pad P32₂ is electrically connected to the internal bonding pad P32₁ through a trace in the semiconductor die 32 (not shown in FIG. 3). The semiconductor die 33 has an internal bonding pad P33₁. The internal pads (or pad) of at least one of the semiconductor dies 31-33 are (or is) located in an internal portion of the corresponding semiconductor die. In this embodiment of FIG. 3, the internal bonding pads P32₁ and P32₂ of the semiconductor die 32 are located in an internal portion 34 of the semiconductor die 32.

The integrated circuit 3 further comprises bonding wires W31, W32 and W33 and an I/O bonding wire W30. The I/O bonding pad P30₂ is electrically connected to the lead finger F2 through the I/O bonding wire W30. Thus, the internal bonding pad P30₁ is electrically connected to the lead finger F2 through the I/O bonding pad P30₂. The internal bonding pad P31₁ is electrically connected to the internal bonding pad P30₁ through the bonding wire W31. The internal bonding pad P32₁ is electrically connected to the internal bonding pad P31₂ through the bonding wire W32. The internal bonding pad P33₁ is electrically connected to the internal bonding pad P32₂ through the bonding wire W33. As shown in FIG. 3, the bonding pads P30₁, P31₁, P31₂, P32₁, P32₂, and P33₁ are electrically connected in series through the bonding wires W31, W32 and W33, sequentially.

In some embodiments, at least one of the bonding pads P30₂, P31₂, and P32₂ is omitted, and the other bonding pad in the same semiconductor as the omitted bonding pad is divided into a first portion and a second portion. For example, if the I/O bonding pad P30₂ of the semiconductor die 30 is omitted, the internal bonding pad P30₁ of the semiconductor die 30 is divided into a first portion and a second portion. The first portion of the internal bonding pad P30₁ is electrically connected to the lead finger F2 of the package through the I/O bonding wire W30, and the second portion thereof is electrically connected to the internal bonding pad P31₁ through the bonding wire W31. Similar to the internal bonding pad P10₁ in FIG. 2, if the internal bonding pad P31₂ of the semiconductor die 31 is omitted, the internal bonding pad P31₁ of the semiconductor die 30 is divided into a first portion and a second portion. The first portion of the internal bonding pad P31₁ is electrically connected to the internal bonding pad P30₁ through the bonding wire W31, and the second portion thereof is electrically connected to the internal bonding pad P32₁ through the bonding wire W32.

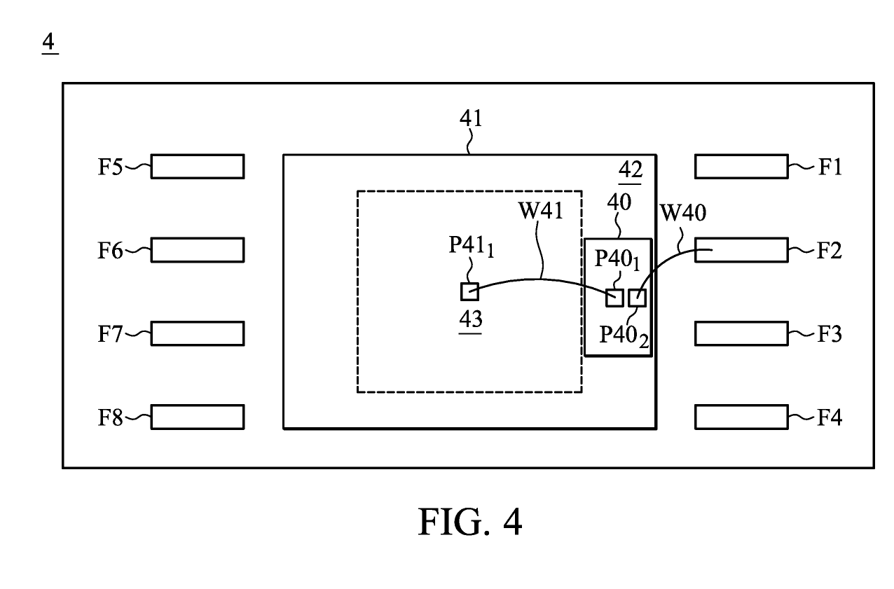

In some embodiments, semiconductor dies in an integrated circuit are overlapped. As shown in FIG. 4, an integrated circuit 4 is mounted in a package and comprises at least two semiconductor dies. In the embodiment of FIG. 4, two overlapped semiconductor dies 40 and 41 are given as an example. The semiconductor die 40 is disposed over the semiconductor die 41 in a periphery portion 42 of the semiconductor die 41. The package comprises a plurality of lead fingers, and in FIG. 4, eight lead fingers F1-F8 are given as an example. Referring to FIG. 4, the semiconductor die 40 has an internal bonding pad P40₁ and an input/output (I/O) bonding pad P40₂, which are electrically connected to one lead finger of the package, for example the lead finger F2. The I/O bonding pad P40₂ is electrically connected to the internal bonding pad P40₁ through a trace in the semiconductor die 40 (not shown in FIG. 4). The semiconductor die 41 has an internal bonding pad P41₁ which is located in an internal portion 43 of the semiconductor die 41. The integrated circuit 4 further comprises an I/O bonding wire W40 and a bonding wire W41. The I/O bonding pad P40₂ is electrically connected to the lead finger F2 through the I/O bonding wire W40. Thus, the internal bonding pad P40₁ is electrically connected to the lead finger F2 through the I/O bonding pad P40₂. The internal bonding pad P41₁ is electrically connected to the internal bonding pad P40₁ through the bonding wire W41.

In some embodiments, the I/O bonding pad P40₂ of the semiconductor die 40 is omitted, and the internal bonding pad P40₁ of the semiconductor die 40 is divided into a first portion and a second portion. The first portion of the internal bonding pad P40₁ is electrically connected to the lead finger F2 of the package through the I/O bonding wire W40, and the second portion thereof is electrically connected to the internal bonding pad P41₁ through the bonding wire W41, similar to the internal bonding pad P10₁ in FIG. 2.

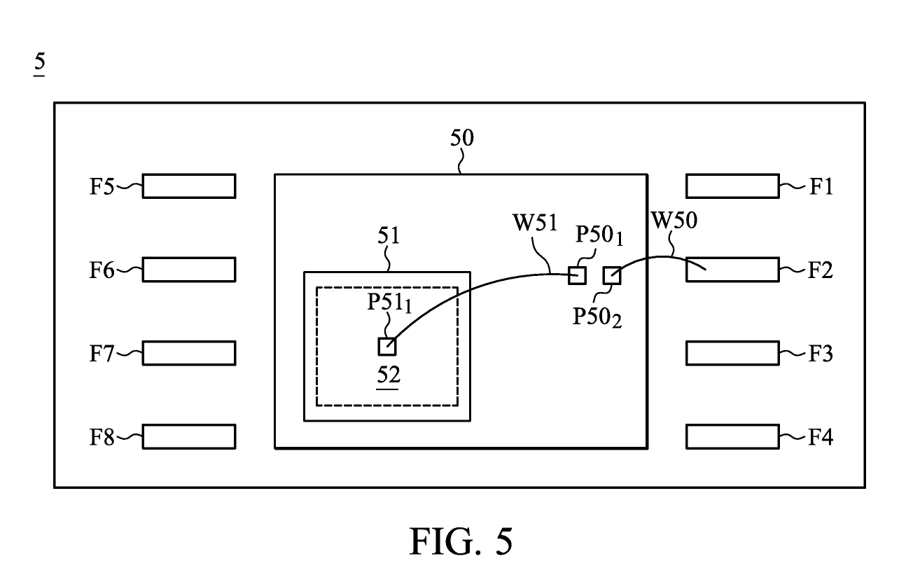

FIG. 5 shows another exemplary embodiment of an integrated circuit with overlapped semiconductor dies. As shown in FIG. 5, an integrated circuit 5 is mounted in a package and comprises two overlapped semiconductor dies 50 and 51. The semiconductor die 51 is disposed over the semiconductor die 50. The package comprises a plurality of lead fingers, and in FIG. 5, eight lead fingers F1-F8 are given as an example. Referring to FIG. 5, the semiconductor die 50 has an internal bonding pad P50₁ and an input/output (I/O) bonding pad P50₂, which are electrically connected to one lead finger of the package, for example the lead finger F2. The I/O bonding pad P50₂ is electrically connected to the internal bonding pad P50₁ through a trace in the semiconductor die 50 (not shown in FIG. 5). The semiconductor die 51 has an internal bonding pad P51₁ which is located in an internal portion 52 of the semiconductor die 51. The integrated circuit 5 further comprises an I/O bonding wire W50 and a bonding wire W51. The I/O bonding pad P50₂ is electrically connected to lead finger F2 through the I/O bonding wire W50. The I/O bonding pad P50₂ is electrically connected to the internal bonding pad P50₁ through a trace in the semiconductor die 50 (not shown in FIG. 5). Thus, the internal bonding pad P50₁ is electrically connected to the lead finger F2 through the I/O bonding pad P50₂. The internal bonding pad P51₁ is electrically connected to the internal bonding pad P50₁ through the bonding wire W51.

According to the above embodiments, semiconductor dies in an integrated circuit can be disposed side-by-side or by overlapping. In other embodiments, semiconductor dies in an integrated circuit can be disposed side-by-side and by overlapping. That is, in an integrated circuit, some semiconductor dies are disposed side-by-side, and some semiconductor dies are disposed by overlapping.

Moreover, the integrated circuits in the above embodiments can be mounted in packages, such as Quad Flat Pack (QFP) and Pin Ball Gate Array (PBGA) packages.

According to the embodiments, an internal portion of at least one of the semiconductor dies is directly electrically connected to a corresponding package lead finger through at least one bonding wire and an I/O bonding wire. Accordingly, the internal portion of the semiconductor die can receive power or signals with sufficient intensity from the package lead fingers.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An integrated circuit mounted in a package, comprising
a first semiconductor die having a first internal bonding pad electrically connected to the package;
a second semiconductor die having a second internal bonding pad located in an internal portion of the second semiconductor die; and
a bonding wire, wherein the second internal bonding pad is electrically connected to the first internal bonding pad through the bonding wire.

2. The integrated circuit as claimed in claim 1, wherein the first semiconductor die and the second semiconductor die are disposed side-by-side.

3. The integrated circuit as claimed in claim 1, wherein the first semiconductor die and the second semiconductor die are disposed by overlapping.

4. The integrated circuit as claimed in claim 3, wherein the first semiconductor die is disposed over the second semiconductor die.

5. The integrated circuit as claimed in claim 4, wherein the first semiconductor die is disposed along a periphery of the second semiconductor die.

6. The integrated circuit as claimed in claim 3, wherein the first semiconductor die is disposed under the second semiconductor die.

7. The integrated circuit as claimed in claim 1, wherein the first semiconductor die further has an input/output (I/O) bonding pad electrically connected to the first internal bonding pad.

8. The integrated circuit as claimed in claim 7 further comprising a trace in the first semiconductor die and between the I/O bonding pad and the first internal bonding pad.

9. The integrated circuit as claimed in claim 7, wherein the package comprises a plurality of lead fingers, and the I/O bonding pad is electrically connected to one of the lead fingers through an I/O bonding wire.

10. The integrated circuit as claimed in claim 1, wherein the first internal bonding pad is divided into a first portion electrically connected to the package and a second portion electrically connected to the second internal bond through the bonding wire.

11. The integrated circuit as claimed in claim 10, wherein the package comprises a plurality of lead fingers, and the first portion of the first internal bonding pad is electrically connected to one of the lead fingers through an I/O bonding wire.

12. An integrated circuit mounted in a package, comprising
a first semiconductor die having a first internal bonding pad electrically connected to the package;
a second semiconductor die having a second internal bonding pad;
a third semiconductor die having a third internal bonding pad, wherein at least one of the second internal bonding pad and the third internal bonding pad is located in an internal portion of the corresponding semiconductor die;
a first bonding wire, wherein the second internal bonding pad is electrically connected to the first internal bonding pad through the first bonding wire; and
a second bonding wire, wherein the third internal bonding pad is electrically connected to the second internal bonding pad through the second bonding wire.

13. The integrated circuit as claimed in claim 12, wherein the first semiconductor die further has an input/output (I/O) bonding pad is electrically connected to the first internal bonding pad.

14. The integrated circuit as claimed in claim 13 further comprising a trace in the first semiconductor die and between the I/O bonding pad and the first internal bonding pad.

15. The integrated circuit as claimed in claim 13, wherein the package comprises a plurality of lead fingers, and the I/O bonding pad is electrically connected to one of the lead fingers through an I/O bonding wire.

16. The integrated circuit as claimed in claim 12, wherein the first internal bonding pad is divided into a first portion electrically connected to the package and a second portion electrically connected to the second internal bond through the first bonding wire.

17. The integrated circuit as claimed in claim 16, wherein the package comprises a plurality of lead fingers, and the first portion of the first internal bonding pad is electrically connected to one of the lead fingers through an I/O bonding wire.

18. The integrated circuit as claimed in claim 12, wherein the second semiconductor die further has a fourth internal bonding pad electrically connected to the second internal bonding pad.

19. The integrated circuit as claimed in claim 18 further comprising a trace in the second semiconductor die and between the second internal bonding pad and the fourth internal bonding pad.

20. The integrated circuit as claimed in claim 12, wherein the second internal bonding pad is divided into a first portion electrically connected to the first internal bonding pad through the first bonding wire and a second portion electrically connected to the third internal bond through the second bonding wire.

21. The integrated circuit as claimed in claim 12 further comprising:
a fourth semiconductor die having a fourth internal bonding pad; and
a third bonding wire, wherein the fourth internal bonding pad is electrically connected to the third internal bonding pad through the third bonding wire.

22. The integrated circuit as claimed in claim 21 wherein the third semiconductor die further has a fifth internal bonding pad electrically connected to the third internal bonding pad.

23. The integrated circuit as claimed in claim 22 further comprising a trace in the third semiconductor die and between the third internal bonding pad and the fifth internal bonding pad.

24. The integrated circuit as claimed in claim 21, wherein the third internal bonding pad is divided into a first portion electrically connected to the second internal bonding pad through the second bonding wire and a second portion electrically connected to the fourth internal bond through the third bonding wire.

25. An integrated circuit mounted in a package, comprising
a first semiconductor die having a first internal bonding pad electrically connected to the package;
a plurality of second semiconductor dies, each having a second internal bonding pad, wherein the second internal bonding pad of at least one of the second semiconductor dies is located in an internal portion of the corresponding semiconductor die;
a plurality of bonding wires, wherein the first internal bonding pad and the second internal bonding pads are electrically connected in series through the bonding wires, sequentially.
